(19) United States
(12) Patent Application Publication
(10) Pub. No.: US 2026/0255768 A1
(43) Pub. Date: Aug. 27, 2026

(54) METHOD FOR PRODUCING AN OPTOELECTRONIC COMPONENT AND OPTOELECTRONIC COMPONENT

(71) Applicant: ams-OSRAM International GmbH, Regensburg (DE)

(72) Inventors: Joo Ding Ngu, Bayan Lepas (MY); Guan Liang Lee, Bayan Lepas (MY)

(21) Appl. No.: 18/874,721

(22) PCT Filed: Jun. 14, 2022
(86) PCT No.: PCT/EP2022/066176

§ 371 Date: Dec. 13, 2024

(51) Int. Cl. H10H 29/856; H10H 29/01

(52) U.S. Cl. CPC H10H 29/856; H10H 29/0363

(57) ABSTRACT

In an embodiment a method for producing an optoelectronic component includes providing a carrier with a semiconductor chip configured to emit electromagnetic radiation, wherein the semiconductor chip comprises a chip mounting face, a top face opposite the chip mounting face, and a side face arranged between the chip mounting face and the top face, and wherein the semiconductor chip is mounted on the carrier with the chip mounting face, applying a first precursor on the carrier such that the side face of the semiconductor chip is at least partially covered with the first precursor, applying a second precursor on the carrier such that the second precursor creeps between the carrier and the first precursor, and curing the first precursor and the second precursor such that the first precursor forms a transparent resin and the second precursor forms a reflective resin.

### CROSS-REFERENCE TO RELATED APPLICATIONS

This patent application is a national phase filing under section 371 of PCT/EP2022/066176, filed Jun. 14, 2022, which is incorporated herein by reference in its entirety.

### TECHNICAL FIELD

A method for producing an optoelectronic component and an optoelectronic component are specified.

### SUMMARY

Embodiments provide a simple and efficient method for producing an optoelectronic component. Further embodiments provide an optoelectronic component with increased brightness.

According to an embodiment of the method, a carrier with a semiconductor chip configured to emit electromagnetic radiation is provided. The semiconductor chip comprises a chip mounting face, a top face opposite the chip mounting face, and a side face arranged between the chip mounting face and the top face. The semiconductor chip is mounted on the carrier with the chip mounting face. Furthermore, the carrier provides in particular an electrical contact for the semiconductor chip. Preferably, more than one semiconductor chip, for example four semiconductor chips, are mounted on the carrier.

According to an embodiment of the method, a first precursor is applied on the carrier such that the side face of the semiconductor chip is at least partially covered with the first precursor. Particularly, the first precursor is in liquid form.

According to an embodiment of the method, a second precursor is applied on the carrier such that the second precursor creeps between the carrier and the first precursor.

Particularly, the second precursor is in liquid form. In particular, the first precursor provides a weight on the second precursor such that the second precursor is prevented from creeping up the side face of the semiconductor chip to the top face. Furthermore, the first precursor preferably changes a contact angle between the side face and the second precursor such that the second precursor is prevented from creeping up the side face of the semiconductor chip to the top face. For example, without the first precursor the contact angle is below 90°, whereas with the first precursor the contact angle is, for example, at least 90°.

According to an embodiment of the method, the first precursor is cured such that the first precursor forms a transparent resin. Particularly, the transparent resin is in solid form.

Here and in the following, a resin is in particular a synthetic polymer, preferably obtainable by irreversible curing of a corresponding precursor. In particular, the first precursor is cured by heating the first precursor to elevated temperatures. For example, the first precursor is heated to at least 50° C., at least 80° C., or at least 100° C. Additionally or alternatively, the first precursor is, in particular, cured by irradiation, for example with UV light, and/or by using a catalyst.

According to an embodiment of the method, the second precursor is cured such that the second precursor forms a reflective resin. Particularly, the reflective resin is in solid form. In particular, the second precursor is cured by heating the second precursor to elevated temperatures. For example, the second precursor is heated to at least 50° C., at least 80° C., or at least 100° C.

According to an embodiment of the method, the transparent resin and the reflective resin are in direct physical contact. In other words, the transparent resin and the reflective resin have a common interface.

According to an embodiment of the method, the transparent resin and the reflective resin cover the side face of the semiconductor chip at least in places. In particular, at least a part of the side face is covered by the transparent resin. Preferably, the reflective resin covers the side face only in places. For example, the transparent resin and/or the reflective resin are in direct physical contact with the side face.

In particular, the transparent resin is adjacent to the top face and covers a region of the side face adjacent to the top face. Preferably, the reflective resin is adjacent to the chip mounting face and covers a region of the side face adjacent to the chip mounting face. For example, the transparent resin and the reflective resin together cover the side face completely.

According to an embodiment of the method, the method comprises:
providing a carrier with a semiconductor chip configured to emit electromagnetic radiation, wherein the semiconductor chip comprises a chip mounting face, a top face opposite the chip mounting face, and a side face arranged between the chip mounting face and the top face and wherein the semiconductor chip is mounted on the carrier with the chip mounting face,
applying a first precursor on the carrier such that the side face of the semiconductor chip is at least partially covered with the first precursor,
applying a second precursor on the carrier such that the second precursor creeps between the carrier and the first precursor, and
curing the first precursor and the second precursor such that the first precursor forms a transparent resin and the second precursor forms a reflective resin.

Preferably, the methods steps are performed in the given order.

In particular, other methods for producing an optoelectronic component having a reflective resin include applying the reflective resin or its precursor in regions far away from the semiconductor chip such that the reflective resin does not cover the side face of the semiconductor chip, creating a stoppage ring around the semiconductor chip which prevents the transparent resin or its precursor from covering the side face of the semiconductor chip, or introducing recesses in the carrier such that a flow of the transparent resin or its precursor is stopped before reaching the semiconductor chip. However, with these methods a part of a bottom face of the carrier around the semiconductor chip is free of the reflective resin which leads to a lower brightness of the optoelectronic component.

With the method described herein it is possible to cover the bottom face of the carrier around the semiconductor chip completely with the reflective resin while only a part of the side face of the semiconductor chip is covered by the reflective resin. In particular, the reflective resin is in direct contact with the side face of the semiconductor chip. In this way, it is possible that an overall brightness of the optoelectronic component is increased.

According to an embodiment of the method, applying the first precursor comprises dispensing the first precursor on the carrier such that the first precursor is in direct physical contact with the side face and creeping of the first precursor up the side face such that the first precursor covers the side face at least in places. In particular, the first precursor is jetted on the carrier such that it is in direct physical contact with the side face. Preferably, an amount of the first precursor applied is such that at least 75%, for example at least 90% of the side face is covered by the first precursor.

If the first precursor is dispensed in a distance from the side face, a covering of the top face of the semiconductor chip with the first precursor and thus the transparent resin is advantageously prevented. Particularly, the top face is free of the first precursor and, after curing, of the transparent resin. In this way, just the necessary amount of the first precursor is applied.

According to an embodiment of the method, applying the second precursor comprises dispensing the second precursor on the carrier in a distance from the side face.

Preferably, the second precursor creeps then between the carrier and the first precursor. In particular, the second precursor is dispensed in a distance from the first precursor. In this way, it can be ensured that the first precursor is not covered by the second precursor.

According to an embodiment of the method, the first precursor comprises or consists of a first polysiloxane. In particular, the first precursor is a silicone. Preferably, the first precursor is free of particles, such as scattering particles.

According to an embodiment of the method, the second precursor comprises a second polysiloxane and scattering particles. In particular, the second precursor is a silicone.

Preferably, the second polysiloxane is different from the first polysiloxane.

Advantageously, the first and the second polysiloxane can be cured under conditions in which the semiconductor chip is not damaged.

According to an embodiment of the method, the second precursor and/or the reflective resin comprise at least 10 wt %, preferably at least 20 wt %, for example about 30 wt % of the scattering particles.

According to an embodiment of the method, the first polysiloxane and the second polysiloxane are immiscible. In other words, the first and the second polysiloxane do not mix. In particular, a boundary surface forms between the first and the second precursor as well as between the transparent resin and the reflective resin. In this way, it can be ensured that the second precursor is prevented from covering the side face of the semiconductor chip up to the top face. Thus, a loss of brightness can advantageously be prevented.

According to an embodiment of the method, the side face of the semiconductor chip is partially free of the second precursor and/or the reflective resin. In other words, only a part of the side face is covered with the second precursor and the reflective resin. In particular, the side face is covered with the second precursor and/or the reflective resin up to a certain height, for example up to at most 50% of the height of the semiconductor chip.

Furthermore, an optoelectronic component is specified. Preferably, the optoelectronic component is produced by the method described herein. Thus, all features and embodiments of the method apply to the optoelectronic component and vice versa.

According to an embodiment, the optoelectronic component comprises a carrier with a semiconductor chip. In particular, the carrier comprises or consist of an epoxy mold compound. The semiconductor chip is configured to emit electromagnetic radiation. The semiconductor chip comprises a chip mounting face, a top face opposite the chip mounting face, and a side face arranged between the chip mounting face and the top face. In particular, the top face is a main emission surface of the semiconductor chip. The semiconductor chip is mounted on the carrier with the chip mounting face. In particular, at least one semiconductor chip, preferably at least two semiconductor chips, for example four semiconductor chips, are mounted on the carrier. Advantageously, the carrier is designed to mechanically stabilize the semiconductor chip. Furthermore, it is possible that the semiconductor chip is electrically contacted via the carrier.

According to an embodiment, the carrier comprises a cavity. In particular, the semiconductor chip is arranged at a bottom face of the cavity. The cavity increases a radiation outcoupling of the optoelectronic component und thus the efficiency of the optoelectronic component.

According to an embodiment, the optoelectronic component comprises a transparent resin covering the side face of the semiconductor chip at least in places. Preferably, the transparent resin is transparent to the electromagnetic radiation emitted by the semiconductor chip. For example, the transparent resin transmits at least 85%, at least 90% or at least 95% of the electromagnetic radiation emitted by the semiconductor chip. In particular, the transparent resin is free of scattering particles or fillers. For example, the top face of the semiconductor chip is free of the transparent resin.

According to an embodiment, the optoelectronic component comprises a reflective resin covering the side face of the semiconductor chip only in places. In particular, the reflective resin is in direct physical contact with the transparent resin. In other words, the transparent resin and the reflective resin share a common interface. Preferably, the reflective resin is diffuse reflective. For example, the reflective resin has a white appearance in daylight. Advantageously, the reflective resin increases the brightness of the optoelectronic component.

According to an embodiment of the optoelectronic component, the reflective resin is arranged between the carrier and the transparent resin. In particular, the transparent resin covers the reflective resin at least in places. Due to this structure, the side face of the semiconductor chip is preferably free of the reflective resin in places. Thus, an outcoupling efficiency of the optoelectronic component is increased.

According to an embodiment, the optoelectronic component comprises a carrier with a semiconductor chip configured to emit electromagnetic radiation, wherein the semiconductor chip comprises a chip mounting face, a top face opposite the chip mounting face, and a side face arranged between the chip mounting face and the top face and wherein the semiconductor chip is mounted on the carrier with the chip mounting face, a transparent resin transparent to the electromagnetic radiation emitted by the semiconductor chip and covering the side face at least in places, and a reflective resin in direct physical contact with the transparent resin and covering the side face only in places, wherein the reflective resin is arranged between the carrier and the transparent resin.

According to an embodiment of the optoelectronic component, the transparent resin and the reflective resin are in direct physical contact with the side face of the semiconductor chip. In particular, the semiconductor chip is completely surrounded by the reflective resin. In this way, the carrier around the semiconductor chip can be completely covered with the reflective resin and thus absorption of the electromagnetic radiation emitted by the semiconductor chip by the carrier is avoided.

According to an embodiment of the optoelectronic component, less than 50% of the side face are covered by the reflective resin. In particular, less than 50% of a height of the side face of the semiconductor chip is covered with the reflective resin. Compared to an optoelectronic component wherein the side face of the semiconductor chip is completely covered with the reflective resin, the brightness of the optoelectronic component can advantageously be increased as less radiation exit area is covered by the reflective resin.

According to an embodiment of the optoelectronic component, the reflective resin comprises scattering particles. In particular, a diffuse reflective property of the reflective resin arises from the scattering particles. Preferably, the scattering particles are inorganic particles, for example comprising a high refractive index. For example, the scattering particles are achromatic particles. The scattering particles preferably comprise or consist of material selected from the group consisting of an oxide, a sulfate, a sulfide, a carbonate, and combinations thereof.

According to an embodiment of the optoelectronic component, the scattering particles comprise or consist of a material selected from the group consisting of TiO₂, ZrO₂, BaSO₄, and mixtures thereof. In particular, these materials are achromatic and comprise a high refractive index.

According to an embodiment of the optoelectronic component, the transparent resin comprises a first cured polysiloxane. Preferably, the first cured polysiloxane is produced from the first polysiloxane in the first precursor of the method described herein. For example, the first cured polysiloxane is a silicone. In particular, a silicone is built from M-units (R₃SiO—) and D-units (—OSiR₂O—).

According to an embodiment of the optoelectronic component, the reflective resin comprises a second cured polysiloxane such as a silicone. Preferably, the second cured polysiloxane is produced from the second polysiloxane in the second precursor of the method described herein. In particular, the scattering particles are homogeneously distributed in the second cured polysiloxane.

According to an embodiment of the optoelectronic component, the first cured polysiloxane is different from the second cured polysiloxane. In this way, a mixing of the transparent resin and the reflective resin during producing the optoelectronic component is preferably prevented. Thus, the side face of the semiconductor chip is only be covered by the reflective resin in places.

According to an embodiment of the optoelectronic component, the reflective resin curves into the transparent resin. In particular, a thickness of the reflective resin comprises a maximum in the region where the reflective resin is covered by the transparent resin.

According to an embodiment of the optoelectronic component, a contact angle (γ) between the side face and the reflective resin is at least 90°. A contact angle of below 90° leads, in particular, to a complete wetting of the side face by the reflective resin. With the contact angle of at least 90° the side face is in particular not completely be wetted by the reflective resin. The contact angle being at least 90° preferably leads to an optoelectronic component having a semiconductor chip only covered in places by the reflective resin and thus having increased brightness.

According to an embodiment of the optoelectronic component, the carrier comprises pedestals at a bottom face. In particular, the semiconductor chip is arranged on the pedestals such that a space is created between the bottom face of the carrier and the semiconductor chip. For example, the pedestals are stand-offs of the carrier or solder joints. Preferably, if the carrier comprises the cavity, the pedestals are arranged at the bottom face of the cavity.

According to an embodiment of the optoelectronic component, a reflective layer is arranged in the space between the bottom face and the semiconductor chip. In particular, the reflective layer increases the radiation outcoupling out of the optoelectronic component as radiation emitted by the semiconductor chip in a direction towards the carrier is reflected by the reflective layer. This effect is in particular not achieved by other optoelectronic components comprising a stoppage ring around the semiconductor chip which prevents the reflective resin from filling the space between the bottom face and the semiconductor chip and thus creating a reflective layer.

According to an embodiment of the optoelectronic component, the reflective layer comprises scattering particles. That is, the reflective layer is preferably diffuse reflective. In particular, the scattering particles of the reflective layer comprise an achromatic and/or inorganic material such as TiO₂, ZrO₂, BaSO₄, and mixtures thereof.

According to an embodiment of the optoelectronic component, the top face of the semiconductor chip is free of the transparent resin. An outcoupling efficiency of the optoelectronic component can be increased if the top face is free of the transparent resin.

According to an embodiment of the optoelectronic component, the reflective resin is free of the transparent resin in places. In other words, the transparent resin does not cover the reflective resin completely. In particular, the transparent resin only covers the reflective resin in a region around the semiconductor chip.

According to an embodiment of the optoelectronic component, the side face comprises or consists of sapphire. That is, the semiconductor chip is, for example, a sapphire chip. In particular, the semiconductor chip is a flip chip.

A flip chip comprises in particular a substrate on which a semiconductor layer sequence with a radiation-generating active zone is epitaxially grown. The substrate is generally transmissive at least to electromagnetic radiation generated in the active region. A side face of the substrate preferably forms a portion of the radiation exit area of the semiconductor chip.

Particularly, the side face of the semiconductor chip is at least partially formed by the side face of the substrate. On a back side of the flip chip, two electrical contacts are usually arranged, which are provided for electrical contacting of the semiconductor chip. The front side of the flip chip is preferably free of electrical contacts.

According to an embodiment of the optoelectronic component, a side wall of the cavity is covered by the reflective resin at least in places. Preferably, the reflective resin also covers the bottom face of the cavity not covered by the semiconductor chip. In other words, the bottom face of the cavity may be completely covered by the semiconductor chip and the reflective resin.

### BRIEF DESCRIPTION OF THE DRAWINGS

Advantageous embodiments and developments of the method for producing an optoelectronic component and the optoelectronic component will become apparent from the exemplary embodiments described below in conjunction with the figures.

FIGS. 1 to 5 show schematic sectional views of stages of a method for producing an optoelectronic component according to an exemplary embodiment;

FIG. 6 shows a schematic sectional view of an optoelectronic component according to a comparative example;

FIG. 7 shows a schematic sectional view of an optoelectronic component according to an exemplary embodiment;

FIG. 8 shows an image of a laboratory test of the method for producing an optoelectronic component;

FIG. 9 shows an image of an optoelectronic component according to an exemplary embodiment;

FIG. 10 shows a scanning electron microscopy (SEM) image of a cross-section of an optoelectronic component according to an exemplary embodiment;

FIG. 11 shows a schematic view of an optoelectronic component according to an exemplary embodiment;

FIG. 12 shows a schematic sectional view of an optoelectronic component according to an exemplary embodiment; and

FIG. 13 shows a schematic sectional view of an optoelectronic component according to an exemplary embodiment.

### DETAILED DESCRIPTION OF ILLUSTRATIVE EMBODIMENTS

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

According to the exemplary embodiment of the method for producing an optoelectronic component 10 of FIGS. 1 to 5, a carrier 1 with a semiconductor chip 2 configured to emit electromagnetic radiation is provided (not shown). The semiconductor chip 2 comprises a chip mounting face 3. The semiconductor chip 2 is mounted with the chip mounting face 3 on the carrier 1. The semiconductor chip 2 further comprises a top face 4 opposite the chip mounting face 3. The top face 4 is in particular be a main emission surface of the semiconductor chip 2. A side face 5 is arranged between the chip mounting face 3 and the top face 4. The semiconductor chip 2 preferably comprise the form of a cuboid. In this case, the side face 5 is formed by the four side faces of the cuboid.

A first precursor 6 is applied on the carrier 1 such that it is in direct physical contact with the side face 5 (FIG. 1). In particular, the first precursor 6 is applied on the carrier 1 around the semiconductor chip 2. The first precursor 6 is applied by dispensing, in particular jetting. The first precursor 6 comprises a first polysiloxane and is free of scattering particles or fillers. For example, a silicone elastomer, which is cured at a temperature of about 150° C., is used as first polysiloxane.

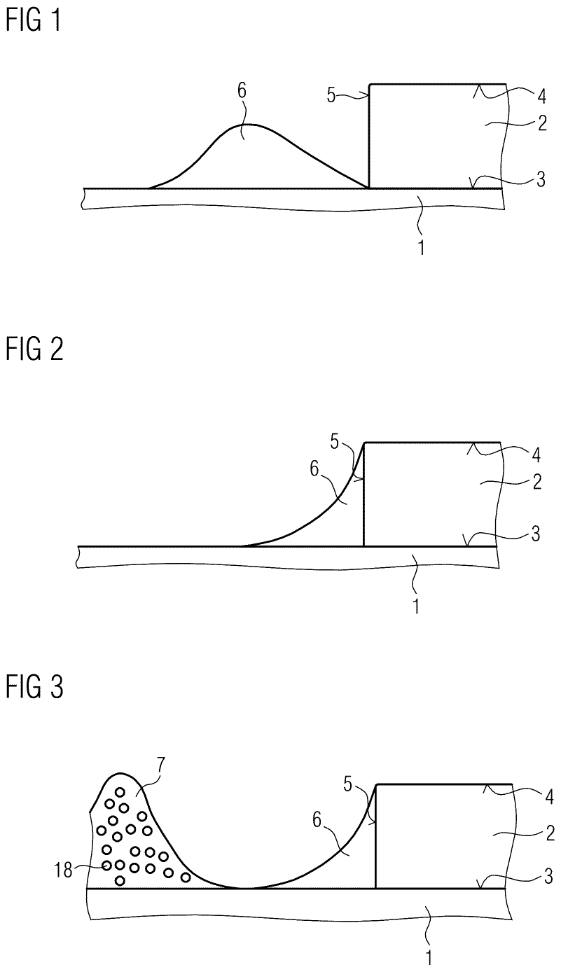

The first precursor 6 creeps up the side face 5 such that the first precursor 6 covers the side face 5 at least in places as shown in FIG. 2. In particular, the first precursor 6 completely covers the side face 5. The first precursor 6 preferably pre-occupies the side face 5.

As shown in FIG. 3, a second precursor 7 is applied on the carrier 1. The second precursor 7 is applied on the carrier in a distance from the semiconductor chip 2 and the first precursor 6 by jetting. The second precursor 7 is in particular applied around the semiconductor chip 2 and the first precursor 6. The second precursor 7 comprises a second polysiloxane and scattering particles 18. The first polysiloxane of the first precursor 6 and the second polysiloxane of the second precursor 7 differ from each other. The first precursor 6 and the second precursor 7 are immiscible. The scattering particles 18 comprise an achromatic inorganic material such as TiO₂, ZrO₂, or BaSO₄. For example, a silicone is used as second polysiloxane and as scattering particles 18 TiO₂ particles having a density of 4.0 g/cm³ and a TiO₂ content of at least 92.5% are used. The second precursor 7 presently comprises about 35 wt % scattering particles 18.

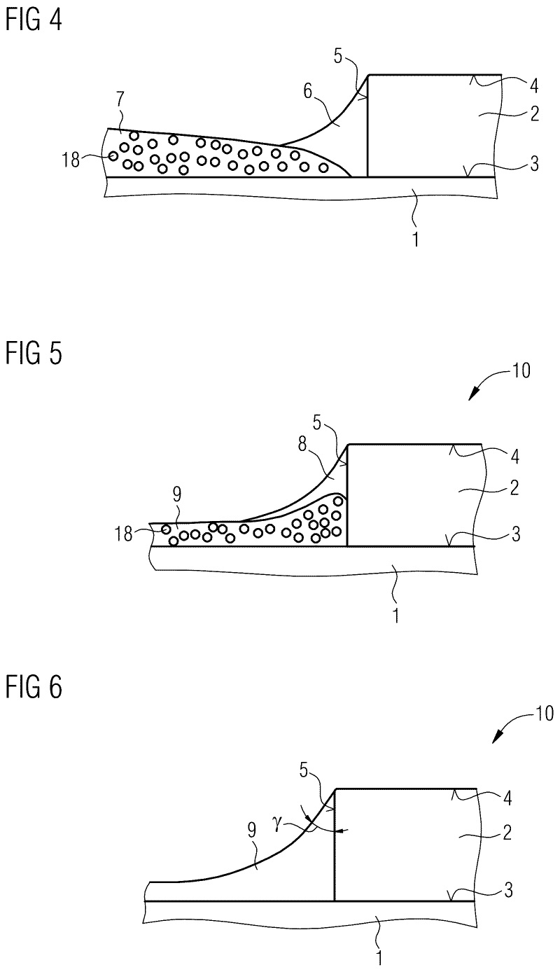

After dispensing of the second precursor 7 on the carrier 1, the second precursor 7 creeps between the carrier 1 and the first precursor 6, as shown in FIG. 4. That is, the second precursor 7 creeps underneath the first precursor 6. This can be explained as the second precursor 7 comprises a higher density as the first precursor 6 because of the scattering particles 18 and/or a composition of the second polysiloxane.

The second precursor 7 creeps up the side face 5 such that it only covers a part of the side face 5. Another part of the side face 5 is covered by the first precursor 6. This effect is explained by the following two mechanisms:

The first precursor 6 can change a contact angle between the second precursor 7 and the side face 5 from wetting to non-wetting. A wetting contact angle is in particular at most 90°. A non-wetting contact angle is, for example, at least 90°.

Furthermore, the first precursor 6 provides a weight on the second precursor 7. In this way, the second precursor 7 is prevented from creeping up the side face 5, in particular completely.

Curing of the first precursor 6 and the second precursor 7, for example at elevated temperatures such as at least 50° C., at least 80° C., or at least 100° C. leads to a formation of a transparent resin 8 and a reflective resin 9. In this way, an optoelectronic component 10 is produced. The first precursor 6 is cured to form the transparent resin 8, whereas the second precursor 7 is cured to form the reflective resin 9. The transparent resin 8 is transparent to the electromagnetic radiation emitted by the semiconductor chip 2. The transparent resin 8 and the reflective resin 9 are in direct physical contact to each other. Furthermore, the transparent resin 8 and the reflective resin 9 are in direct physical contact with the side face 5. Thereby, the transparent resin 8 and the reflective resin 9 each cover the side face 5 in places. Additionally, the reflective resin 9 is in direct physical contact with the carrier 1. The transparent resin 8 only covers part of the reflective resin 9. The top face 5 of the semiconductor chip 2 is free of the transparent resin 8 and the reflective resin 9.

FIG. 6 shows an optoelectronic component 10 according to a comparative example. The optoelectronic component 10 comprises a carrier 1 and a semiconductor chip 2 arranged on the carrier 1 via its chip mounting face 3. The semiconductor chip 2 comprises a side face 5 arranged between the chip mounting face 3 and a top face 4 opposite the chip mounting face 3. The side face 5 is completely covered with a reflective resin 9 which comprises a first cured polysiloxane and scattering particles 18. A contact angle γ between the reflective resin 9 and the side face 5 is below 90°. This corresponds to a complete wetting of the side face 5 by the reflective resin 9. Due to the complete wetting of the side face 5, the radiation emitted by the semiconductor chip 2 is only emitted via the top face 4.

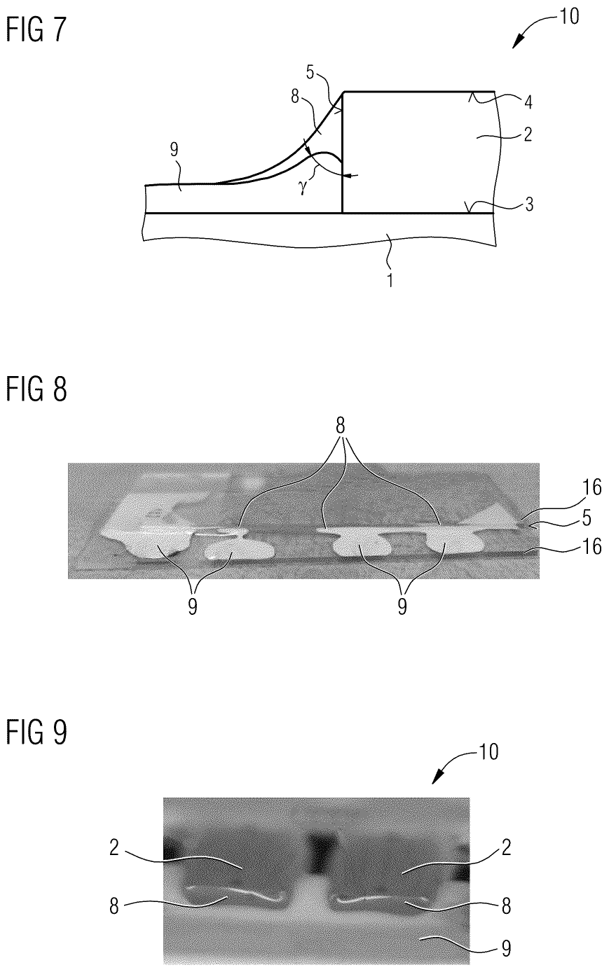

FIG. 7 shows an optoelectronic component 10 according to an exemplary embodiment. The optoelectronic components 10 comprises the carrier 1 and a semiconductor chip 2 configured to emit electromagnetic radiation. The semiconductor chip 2 comprises a chip mounting face 3, a top face 4 opposite the chip mounting face 3, and a side face 5 arranged between the chip mounting face 3 and the top face 4. The optoelectronic component 10 further comprises a transparent resin 8 and a reflective resin 9. The transparent resin 8 is transparent to the electromagnetic radiation emitted by the semiconductor chip 2. The transparent resin 8 and the reflective resin 9 each cover the side face 5 in places. The transparent resin 8 and the reflective resin 9 are in direct physical contact with the side face 5. The reflective resin 9 is arranged between the carrier 1 and the transparent resin 8. A part of the reflective resin 9 is free of the transparent resin 8. The reflective resin 9 is in direct physical contact with the carrier 1 and the transparent resin 8.

A thickness of the reflective resin 9 depends from a distance to the side face 4. In particular, the reflective resin 9 curves into the transparent resin 8. That is, starting from the side face 4, the thickness of the reflective resin 9 increases to reach a maximum and then the thickness of the reflective resin 9 decreases to reach a minimum. In particular, the maximum is in a region of the reflective resin 9 covered by the transparent resin 8.

Due to the transparent resin 8, a contact angle γ between the side face 5 and the reflective resin 9 is at least 90°. That is, the reflective resin 9 forms a non-wetting contact angle γ with the side face 5. As the side face 5 is only covered by the reflective resin 9 in parts, the radiation emitted by the semiconductor chip 2 leaves the semiconductor chip via the top face 4 and the side face 5 not covered by the reflective resin. In this way, the efficiency of the optoelectronic component 10 is increased.

In FIG. 8, a laboratory test of the method for producing an optoelectronic 10 is shown by means of an image. An effectiveness of the method is proven by the laboratory test.

For the laboratory test, two glass carriers 16 are stacked with an offset. On one side of the stacked glass carriers 16 (right side) a first precursor 6 and afterwards a second precursor 7 are applied and cured to give a transparent resin 8 and a reflective resin 9. On the other side (left side) only the second precursor 7 is applied and cured. The composition of the first precursor 6 and the second precursor 7 is the same as described in combination with FIGS. 1 to 5.

As can be seen from the image of FIG. 8, the right side of the stacked glass carriers 16 which was treated with the first precursor 6 and the second precursor 7 shows a side face 5 of the top glass carrier 16 which is covered by the transparent resin 8 and the reflective resin 9. Thereby, only a part of the side face 5 is covered by the reflective resin 9.

In contrast, the left side of the stacked glass carriers 16 which was only treated with the second precursor 7 shows a side face 5 of the top glass carriers 16 which is completely covered by the reflective resin 9.

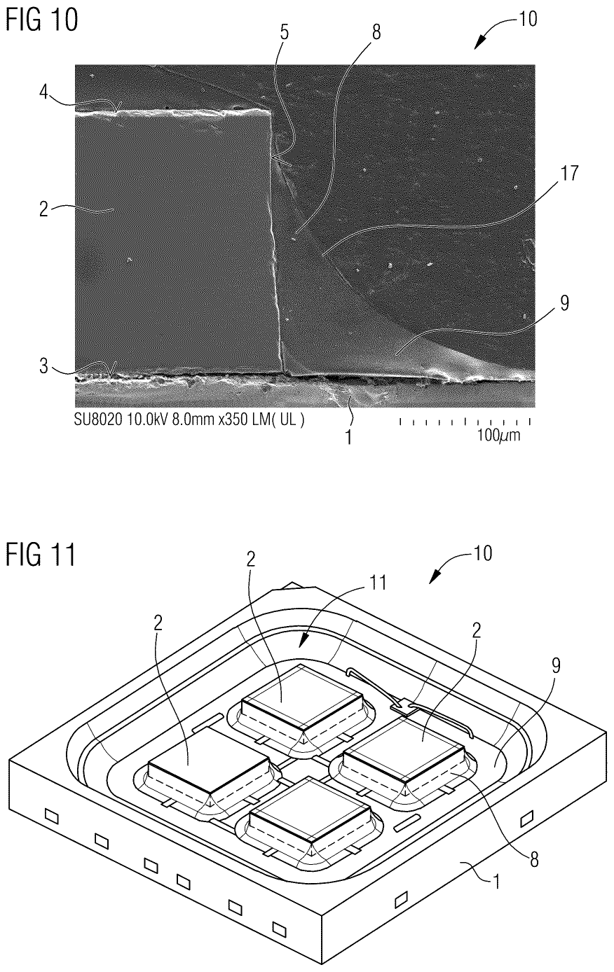

FIG. 9 shows an image of a section of an optoelectronic component 10 according to an exemplary embodiment. The optoelectronic component 10 comprises two semiconductor chips 2 and a carrier 1. The carrier 1 is presently completely covered 5 by the semiconductor chips 2 and a reflective resin 9. The semiconductor chips 2 each comprise a side face 5. The side face 5 is covered by the reflective resin 9 and a transparent resin 8. The side face 5 is only partially covered by the reflective resin 9.

In FIG. 10, a SEM image of a cross-section of an optoelectronic component 10 according to an exemplary embodiment is shown. In particular, FIG. 10 shows a cross-sectional view of the optoelectronic component 10 shown in FIG. 9. The optoelectronic component 10 of FIG. 10 comprises a carrier 1. A semiconductor chip 2 configured to emit electromagnetic radiation is mounted on the carrier 1 via a chip mounting face 3. The semiconductor chip 2 further comprises a top face 4 opposite the chip mounting face 3 and a side face 5 arranged between the chip mounting face 3 and the top face 4.

The side face 5 and the carrier 1 are in direct physical contact to a reflective resin 9. The reflective resin 9 comprises a first cured polysiloxane and scattering particles 18, for example comprising or consisting of TiO₂. In particular, the reflective resin 9 comprises a cured silicone and TiO₂ particles having a density of 4.0 g/cm³ and a TiO₂ content of at least 92.5%.

Presently, the reflective resin 9 comprises about 35 wt % of the scattering particles 18. Less than 50% of the side face 5 is covered by the reflective resin 9. In particular, less than 50% of a height of the side face 5 is covered by the reflective resin 9.

A transparent resin 8 comprising a silicone cured at a temperature of about 150° C. is arranged on the reflective resin 9. The transparent resin 8 covers a part of the side face 5 of the semiconductor chip 2. The reflective resin 9 curves into the transparent resin 8. The transparent resin 8 and the reflective resin 9 are in direct physical contact to each other. Thus, the transparent resin 8 and the reflective resin 9 share a common interface 17. The top face 4 of the semiconductor chip 2 is free of the transparent resin 8 and the reflective resin 9.

In FIG. 11 a schematic view of an optoelectronic component 10 according to an exemplary embodiment is shown. The optoelectronic component 10 comprises a carrier 1 comprising an epoxy mold compound. The carrier 1 comprises a cavity 11 having a bottom face 13 and a side wall 15. On the bottom face 13 of the cavity 11, four semiconductor chips 2 are mounted via their chip mounting faces 3. Each semiconductor chip 2 is configured to emit electromagnetic radiation. Each semiconductor chip 2 comprises a top face 4 opposite the chip mounting face 3 and a side face 5 arranged between the top face 4 and the chip mounting face 3. In particular, the side face 4 completely surrounds the semiconductor chip 2.

The optoelectronic component 10 further comprises a transparent resin 8 and a reflective resin 9 which are both arranged in the cavity 11 of the carrier 1. The transparent resin 8 and the reflective resin 9 each cover the side face 5 of the semiconductor chips 2 in places. In particular, a part of the side face 5 is free of the reflective resin 9. The reflective resin 9 is arranged between the carrier 1 and the transparent resin 8. Furthermore, the reflective resin 9 curves into the transparent resin 8. The reflective resin 9 is partially free of the transparent resin 8. The top face 4 of the semiconductor chips 2 is free of the transparent resin 8.

As shown in FIG. 11, the bottom face 13 and the side wall 15 of the cavity 11 are at least partially covered by the reflective resin 9. The reflective resin 9 partially covering the side wall 15 can be explained as during producing the optoelectronic component 10, the precursor for the reflective resin 9 creeps up the side wall until to a certain point.

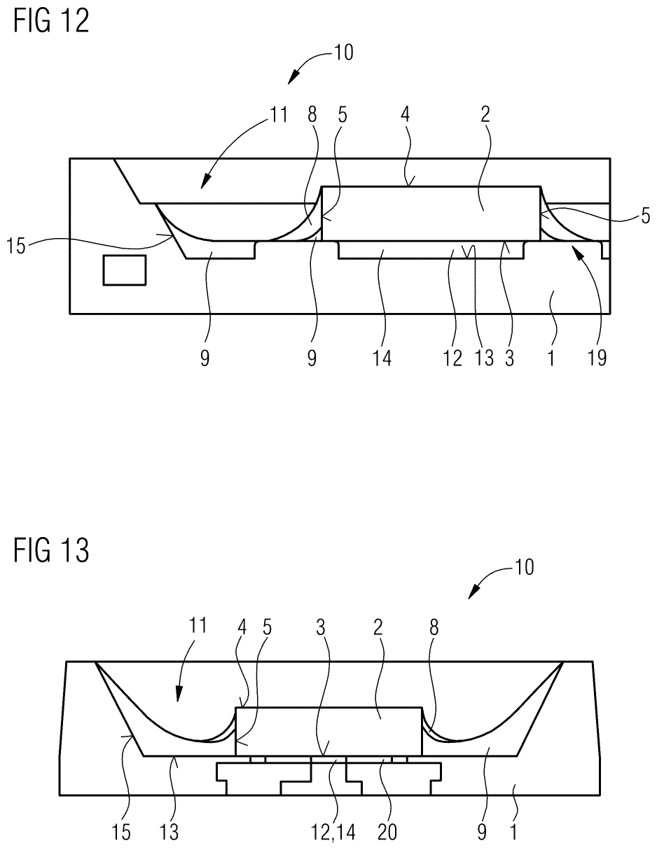

A schematic sectional view of an optoelectronic component 10 according to an exemplary embodiment is shown in FIG. 12. In particular, FIG. 12 shows a schematic cross-section of the optoelectronic component of FIG. 11. The optoelectronic component of FIG. 12 comprises a carrier 1 and a semiconductor chip 2. The semiconductor chip 2 is presently a flip chip.

The carrier 1 comprises a cavity 11 in which the semiconductor chip 2 is arranged. The cavity 11 comprises a side wall 15 and a bottom face 13. The bottom face 13 is presently the bottom face of the carrier 1. The bottom face 13 and at least a part of the side wall 15 are covered by a reflective resin 9. The reflective resin 9 comprises a second cured polysiloxane and scattering particles 18, for example comprising or consisting of TiO₂. A thickness of the reflective resin 9 on the side wall 15 decreases with a distance away from the bottom face 13. The reflective resin 9 is diffuse reflective.

The reflective resin 9 is partially covered by a transparent resin 8. That is, the reflective resin 9 is arranged between the transparent resin 8 and the carrier 1. The reflective resin 9 is in direct physical contact to the carrier 1 and the transparent resin 8. The transparent resin 8 comprises a first cured polysiloxane and is transparent to the electromagnetic radiation emitted by the semiconductor chip 2. The first cured polysiloxane and the second cured polysiloxane differ from each other.

A semiconductor chip 2 configured to emit electromagnetic radiation is arranged on the bottom face 13 of the cavity 11 of the carrier 1. The semiconductor chip 2 comprises a chip mounting face 3, a top face 4 opposite the chip mounting face 3, and a side face 5 arranged between the chip mounting face 3 and the top face 4. The side face 5 comprises or consists of sapphire. The top face 4 is free of the transparent resin 8 and the reflective resin 9. The side face 5 is covered at least partially by the transparent resin 8 and the reflective resin 9. The reflective resin 9 only covers the side face 5 in places. A thickness of the transparent resin 8 on the side face 5 decreases with increasing distance to the chip mounting face 3. A thickness of the transparent resin 8 on the reflective resin 9 also decreases with increasing distance to the side face 5.

Presently, the carrier 1 comprises pedestals arranged at the bottom face 13. Presently, the pedestals are stand-offs 19 of the carrier 1. The stand-offs 19 are protruding features on the bottom face 13 of the carrier 1. The semiconductor chip 2 is arranged on the stand-offs 19. In this way, a space 12 is created between the bottom face 13 and the semiconductor chip 2. The space 12 is filled with a reflective layer 14. That is, the reflective layer 14 is arranged between the bottom face 13 and the semiconductor chip 2. In particular, the reflective layer 14 fills the space 12 at least partially, preferably completely. The reflective layer 14 is diffuse reflective. In particular, the reflective layer 14 comprises scattering particles comprising or consisting of TiO₂, ZrO₂, or BaSO₄.

The optoelectronic component 10 shown in FIG. 13 comprises a carrier 1 with a cavity 11 having a bottom face 13. A single semiconductor chip 2 is arranged on the bottom face 13 via solder joints 20. Due to the solder joints 20 a space 12 is created between the semiconductor chip 12 and the bottom face 13 of the carrier 1. The space 12 is filled with a reflective layer 14 which is diffuse reflective.

A side face 5 of the semiconductor chip 2 is covered with a reflective resin 9 and a transparent resin 8. A top face 4 of the semiconductor chip 2 is free of both the transparent resin 8 and the reflective resin 9. The transparent resin 8 covers the reflective resin 9 in places.

Thereby, the transparent resin 8 and the reflective resin 9 are in direct physical contact. The transparent resin 8 is free of a filler or scattering particles. The reflective resin 9 comprises scattering particles 18. Thus, the reflective resin 9 is diffuse reflective. In particular, the reflective resin 9 and the transparent resin 9 are the same as described in combination with FIG. 12.

The reflective resin 9 is in direct physical contact with the bottom face 13 and a side wall 15 of the carrier 1. That is, the reflective resin 9 is arranged between the transparent resin 8 and the carrier 1.

The features and exemplary embodiments described in connection with the figures can be combined with each other according to further exemplary embodiments, even if not all combinations are explicitly described. Furthermore, the exemplary embodiments described in connection with the figures may have alternative or additional features as described in the general part.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-20. (canceled)

21. A method for producing an optoelectronic component, the method comprising:
providing a carrier with a semiconductor chip configured to emit electromagnetic radiation, wherein the semiconductor chip comprises a chip mounting face, a top face opposite the chip mounting face, and a side face arranged between the chip mounting face and the top face, and wherein the semiconductor chip is mounted on the carrier with the chip mounting face;
applying a first precursor on the carrier such that the side face of the semiconductor chip is at least partially covered with the first precursor;
applying a second precursor on the carrier such that the second precursor creeps between the carrier and the first precursor; and
curing the first precursor and the second precursor such that the first precursor forms a transparent resin and the second precursor forms a reflective resin.

22. The method according to claim 21, wherein applying the first precursor comprises:
dispensing the first precursor on the carrier such that the first precursor is in direct physical contact with the side face, and
creeping the first precursor up the side face such that the first precursor covers the side face at least in places.

23. The method according to claim 21, wherein applying the second precursor comprises dispensing the second precursor on the carrier in a distance from the side face.

24. The method according to claim 21, wherein the first precursor comprises a first polysiloxane.

25. The method according to claim 24, wherein the second precursor comprises a second polysiloxane and scattering particles, and wherein the second polysiloxane is different from the first polysiloxane.

26. The method according to claim 25, wherein the first polysiloxane and the second polysiloxane are immiscible.

27. The method for according to claim 21, wherein the side face is partially free of the second precursor and/or the reflective resin.

28. The method for according to claim 21,
wherein the transparent resin and the reflective resin are in direct physical contact, and
wherein the transparent resin and the reflective resin cover the side face at least in places.

29. An optoelectronic component comprising:
a carrier with a semiconductor chip configured to emit electromagnetic radiation, wherein the semiconductor chip comprises a chip mounting face, a top face opposite the chip mounting face, and a side face arranged between the chip mounting face and the top face, and wherein the semiconductor chip is mounted on the carrier with the chip mounting face;
a transparent resin transparent to the electromagnetic radiation and covering the side face at least in places; and
a reflective resin in direct physical contact with the transparent resin and covering the side face only in places,
wherein the reflective resin is arranged between the carrier and the transparent resin.

30. The optoelectronic component according to claim 29, wherein the transparent resin and the reflective resin are in direct physical contact with the side face.

31. The optoelectronic component according to claim 29, wherein less than 50% of the side face are covered by the reflective resin.

32. The optoelectronic component according to claim 29, wherein the reflective resin comprises scattering particles.

33. The optoelectronic component according to claim 32, wherein the scattering particles comprise a material selected from the group consisting of TiO₂, ZrO₂, BaSO₄, and mixtures thereof.

34. The optoelectronic component according to claim 29,
wherein the transparent resin comprises a first cured polysiloxane,
wherein the reflective resin comprises a second cured polysiloxane, and
wherein the first cured polysiloxane is different from the second cured polysiloxane.

35. The optoelectronic component according to claim 29, wherein the reflective resin curves into the transparent resin.

36. The optoelectronic component according to claim 29, wherein a contact angle (y) between the side face and the reflective resin is at least 90°.

37. The optoelectronic component according to claim 29,
wherein the carrier comprises pedestals at a bottom face,
wherein the semiconductor chip is arranged on the pedestals such that a space is created between the bottom face and the semiconductor chip,
wherein a reflective layer is arranged in the space, and
wherein the reflective layer comprises scattering particles.

38. The optoelectronic component according to claim 29, wherein the top face of the semiconductor chip is free of the transparent resin.

39. The optoelectronic component according to claim 29, wherein the reflective resin is free of the transparent resin in places.

40. The optoelectronic component according to claim 29, wherein the side face comprises sapphire.
